(19) United States
(12) Patent Application Publication
(10) Pub. No.: US 2025/0277881 A1
(43) Pub. Date: Sep. 4, 2025

(54) Method and Apparatus for Clock Synchronization in MRI System, and MRI System

(71) Applicant: Siemens Healthineers AG, Forchheim (DE)

(72) Inventors: Li Chen Zhu, Shenzhen (CN); JianMin Wang, Shenzhen (CN); Jia Lin He, Shenzhen (CN); Ting Chen, Shenzhen (CN)

(73) Assignee: Siemens Healthineers AG, Forchheim (DE)

(21) Appl. No.: 19/059,519

(22) Filed: Feb. 21, 2025

(30) Foreign Application Priority Data
Feb. 29, 2024 (CN) 202410231533.4

(51) Int. Cl. G01R 33/36

(52) U.S. Cl. CPC G01R 33/3692; G01R 33/3621

(57) ABSTRACT

The disclosure describes clock synchronization in an MRI system by sending a signal containing MR data and training data from an MR wireless coil end.

### CROSS-REFERENCE TO RELATED APPLICATIONS

The present application claims priority to and the benefit of China patent application no. CN 202410231533.4, filed on Feb. 29, 2024, the contents of which are incorporated herein by reference in their entirety.

### TECHNICAL FIELD

The present disclosure relates to the technical field of MRI (magnetic resonance imaging) and, in particular, to a method and apparatus for clock synchronization in an MRI system, and an MRI system.

### BACKGROUND

In data communication applications, a sending end and a receiving end must maintain clock synchrony to ensure the correctness and reliability of data receiving. Furthermore, in comparison with conventional coils, wireless coils in MR systems have characteristics such as not needing to be connected to the examination table, giving a good user experience and being easy to clean, and for these reasons are expected to become a new application trend in MR (magnetic resonance) imaging.

### SUMMARY

Embodiments of the present disclosure achieve synchronization of a data transmission clock and the system clock in the MRI system. The MRI system uses a second clock as a reference clock, and uses pre-stored original training data to perform coherence phase analysis of the training data in the signal to obtain a phase offset between the second clock and the first clock, and obtains the MR data from the signal by parsing. Also, the phase offset between the second clock and the first clock is used to adjust the second clock, so that the second clock and the first clock are synchronized. A system clock frequency is used as a sampling frequency to sample a clock signal output by the second clock, and a phase offset between the system clock and the second clock is used based upon the sampled signal. The MR data is synchronized to a system clock domain according to the phase offset between the system clock and the second clock.

That is, in view of the above, one aspect of embodiments of the present disclosure proposes a method and apparatus for clock synchronization in an MRI system to achieve synchronization of a system clock and a data transmission clock in an MRI system without adding any links; another aspect proposes an MRI system to achieve synchronization of a system clock and a data transmission clock in an MRI system without adding any links.

A method for clock synchronization in a magnetic resonance imaging (MRI) system is provided, the method comprising:
sending a signal containing MR data and training data from an MR wireless coil end, the MR data being data obtained by sampling according to a first clock by the MR wireless coil end, and the training data being inserted in the MR data;
the MRI system using a second clock as a reference clock, receiving the signal from the MR wireless coil end, using pre-stored original training data to perform coherence phase analysis of the training data in the signal to obtain a phase offset between the second clock and the first clock, and obtaining the MR data from the signal by parsing, wherein the original training data is data identical to the training data initially inserted in the MR data at the MR wireless coil end;
using the phase offset between the second clock and the first clock to adjust the second clock, so that the second clock and the first clock are synchronized;
using a system clock frequency as a sampling frequency to sample a clock signal output by the second clock, and calculating a phase offset between the system clock and the second clock on the basis of the sampled signal;
synchronizing the MR data obtained by parsing to a system clock domain according to the phase offset between the system clock and the second clock.

The training data being inserted in the MR data means that each training symbol set is inserted in the MR data according to a preset first interval, wherein training symbols in each training symbol set are inserted in the MR data according to a preset second interval, each training symbol set and the MR data in which it is inserted form a training sequence, and the original training data is data identical to an original training symbol set initially inserted in the MR data at the MR wireless coil end;
the step of using pre-stored original training data to perform coherence phase analysis of the training data in the signal, to obtain a phase offset between the second clock and the first clock, comprises:
using a sliding window of the same length as one training sequence, sliding the sliding window over the signal with a preset first length as a sliding step length, extracting suspected training symbols from within the window according to the preset second interval on each occasion that sliding is performed, forming a suspected training symbol set from the suspected training symbols extracted from within the window, calculating a correlation of the suspected training symbol set and the original training symbol set, and respectively calculating a corresponding phase offset between the second clock and the first clock according to each periodically occurring correlation peak value;
the step of obtaining the MR data from the signal by parsing comprises:
confirming the suspected training symbol set in the window corresponding to each periodically occurring correlation peak value as a true training symbol set, and using data other than the true training symbol set within the window as MR data.

The training symbol set is a plurality,
the step of calculating a correlation of the suspected training symbol set and the original training symbol set comprises:
performing a convolution operation on the suspected training symbol set and the original training symbol set, and calculating the modulus of a convolution result;
the step of respectively calculating a corresponding phase offset between the second clock and the first clock according to each periodically occurring correlation peak value comprises:
based on a peak value of the modulus of each periodically occurring convolution result, respectively calculating a phase angle of the convolution result corresponding to each peak value, each phase angle respectively being a phase offset between the second clock and the first clock.

The second clock is a clock generated by a voltage-controlled oscillator, and the step of using the phase offset between the second clock and the first clock to adjust the second clock comprises:
based on a preset linear relationship between phase offset and duty cycle, converting the phase offset between the second clock and the first clock to a square wave signal with a corresponding duty cycle, outputting the square wave signal to an integrator, and using a level output by the integrator to adjust a frequency of a clock signal output by the voltage-controlled oscillator.

The first clock is a free-running clock.

Before the step of obtaining the MR data and training data by parsing from the signal from the MR wireless coil end, using a second clock as a reference clock, the method further comprises:
obtaining a pre-defined maximum frequency difference between the second clock and the first clock;
based on a transmission rate of a wireless system containing the MR wireless coil, a transmission rate of a wireless module of the MR wireless coil, and the length of the training sequence containing the training data used in a single coherence phase analysis, calculating a maximum phase offset corresponding to the pre-defined maximum frequency difference between the second clock and the first clock;
if the maximum phase offset is greater than 90°, re-selecting a first clock and/or second clock with a smaller pre-defined frequency error range, or reducing the length of the training sequence containing the training data used in a single coherence phase analysis.

The step of synchronizing the MR data obtained by parsing to a system clock domain according to the phase offset between the system clock and the second clock comprises:
subjecting the MR data obtained by parsing to phase offset correction according to the phase offset between the system clock and the second clock, and outputting the phase-offset-corrected MR data at an MR data sampling frequency of the MR wireless coil end according to the system clock.

The step of subjecting the MR data obtained by parsing to phase offset correction according to the phase offset between the system clock and the second clock comprises:

$${g}_{i} = {\sum }_{j = i - m + 1}^{j = i + m} {g}_{d} ( j ) sinc ( \frac{a {0}_{i}}{2 π} - ( j - i ) )$$

where gᵢ is the MR data resulting from the ith phase offset correction, i≥1, 2m is a preset number of interpolations, m being a preset positive integer, g_{d}(j) is the jth item of MR data obtained by parsing, j≥1, a0ᵢ is the phase offset between the system clock and the second clock that corresponds to the MR data resulting from the ith phase offset correction, a0ᵢ being expressed in radians, and sinc is a function name.

The a0ᵢ is the mean value of the (n*(i−1)+1)th to the (n*i)th phase offsets between the system clock and the second clock, calculated on the basis of the sampled signal when the system clock frequency is used as a sampling frequency to sample the clock signal output by the second clock, wherein n is the ratio of the system clock frequency to the MR data sampling frequency of the MR wireless coil end.

An apparatus for clock synchronization in a magnetic resonance imaging (MRI) system, the apparatus comprising:
a first phase offset acquisition module, configured to use pre-stored original training data to perform coherence phase analysis of training data in a signal from a magnetic resonance (MR) wireless coil end, using a second clock as a reference clock, to obtain a phase offset between the second clock and the first clock, and obtain MR data by parsing from the signal, wherein the signal contains MR data and training data, the MR data being data obtained by sampling according to the first clock by the MR wireless coil end, and the training data being inserted in the MR data; and the original training data is data identical to the training data initially inserted in the MR data at the MR wireless coil end;
a first synchronization module, configured to use the phase offset between the second clock and the first clock to adjust the second clock, so that the second clock and the first clock are synchronized;
a second phase offset acquisition module, configured to use a system clock frequency as a sampling frequency to sample a clock signal output by the second clock, and calculate a phase offset between the system clock and the second clock on the basis of the sampled signal;
a second synchronization module, configured to synchronize the MR data obtained by parsing to a system clock domain according to the phase offset between the system clock and the second clock.

The training data being inserted in the MR data means that each training symbol set is inserted in the MR data according to a preset first interval, wherein training symbols in each training symbol set are inserted in the MR data according to a preset second interval, each training symbol set and the MR data in which it is inserted form a training sequence, and the original training data is data identical to an original training symbol set initially inserted in the MR data at the MR wireless coil end;
the first phase offset acquisition module using pre-stored original training data to perform coherence phase analysis of training data in a signal from an MR wireless coil end, to obtain a phase offset between the second clock and the first clock, comprises:
using a sliding window of the same length as one training sequence, sliding the sliding window over the signal with a preset first length as a sliding step length, extracting suspected training symbols from within the window according to the preset second interval on each occasion that sliding is performed, forming a suspected training symbol set from the suspected training symbols extracted from within the window, calculating a correlation of the suspected training symbol set and the original training symbol set, and respectively calculating a corresponding phase offset between the second clock and the first clock according to each periodically occurring correlation peak value;
the first phase offset acquisition module obtaining MR data by parsing from the signal comprises:
confirming the suspected training symbol set in the window corresponding to each periodically occurring correlation peak value as a true training symbol set, and using data other than the true training symbol set within the window as MR data.

The training symbol set is a plurality,
the first phase offset acquisition module calculating a correlation of the suspected training symbol set and the original training symbol set comprises:
performing a convolution operation on the suspected training symbol set and the original training symbol set, and calculating the modulus of a convolution result;
the first phase offset acquisition module respectively calculating a corresponding phase offset between the second clock and the first clock, according to each periodically occurring correlation peak value, comprises:
based on a peak value of the modulus of each periodically occurring convolution result, respectively calculating a phase angle of the convolution result corresponding to each peak value, each phase angle respectively being a phase offset between the second clock and the first clock.

The second clock is a clock generated by a voltage-controlled oscillator, and the first synchronization module using the phase offset between the second clock and the first clock to adjust the second clock comprises:
based on a preset linear relationship between phase offset and duty cycle, converting the phase offset between the second clock and the first clock to a square wave signal with a corresponding duty cycle, outputting the square wave signal to an integrator, and using a level output by the integrator to adjust a frequency of a clock signal output by the voltage-controlled oscillator.

The second synchronization module synchronizing the MR data obtained by parsing to a system clock domain, according to the phase offset between the system clock and the second clock, comprises:
subjecting the MR data obtained by parsing to phase offset correction according to the phase offset between the system clock and the second clock, and outputting the phase-offset-corrected MR data at an MR data sampling frequency of the MR wireless coil end according to the system clock.

The second synchronization module subjecting the MR data obtained by parsing to phase offset correction, according to the phase offset between the system clock and the second clock, comprises:

$${g}_{i} = {\sum }_{j = i - m + 1}^{j = i + m} {g}_{d} ( j ) sinc ( \frac{a {0}_{i}}{2 π} - ( j - i ) )$$

where gᵢ is the MR data resulting from the ith phase offset correction, i≥1, 2m is a preset number of interpolations, m being a preset positive integer, g_{d}(j) is the jth item of MR data obtained by parsing, j≥1, a0ᵢ is the phase offset between the system clock and the second clock that corresponds to the MR data resulting from the ith phase offset correction, a0ᵢ being expressed in radians, and sinc is a function name.

The second synchronization module obtains a0ᵢ in the following way:
using as a0ᵢ the mean value of the (n*(i−1)+)th to the (n*i)th phase offsets between the system clock and the second clock which are calculated by the second phase offset acquisition module, wherein n is the ratio of the system clock frequency to the MR data sampling frequency of the MR wireless coil end.

The apparatus for clock synchronization in an MRI system is located on a programmable logic array (FPGA).

A magnetic resonance imaging (MRI) system, the MRI system comprising the apparatus for clock synchronization in an MRI system as described in any one of the embodiments above.

The apparatus for clock synchronization in an MRI system is located at a magnetic resonance (MR) system end;
the MRI system further comprises: a first analog-to-digital converter (ADC) and a first wireless module, which are located at a magnetic resonance (MR) wireless coil end, and a second wireless module and a second ADC which are located at the MR system end, wherein:
the first ADC is configured to use a first clock as a reference clock, convert an MR signal acquired by a wireless coil from an analog MR signal to a digital MR signal, sample the digital MR signal at a preset sampling frequency to obtain sampled MR data, insert original training data in the MR data obtained by sampling according to a preset training data insertion rule to obtain a training sequence, and transmit the training sequence to the first wireless module;
the first wireless module is configured to use the first clock as a reference clock, receive the training sequence sent by the first ADC, modulate a frequency of the training sequence to a preset frequency and then send out same via a wireless antenna;
the second wireless module is configured to use a second clock as a reference clock, receive the training sequence from a wireless antenna, subject the training sequence to zero intermediate frequency processing to convert same to a baseband signal, and then transmit same to the second ADC;
the second ADC is configured to use the second clock as a reference clock, receive the baseband signal sent by the second wireless module, convert the baseband signal to a digital signal and then send same to the apparatus for clock synchronization in an MRI system;
and the first phase offset acquisition module in the apparatus for clock synchronization in an MRI system using pre-stored original training data to perform coherence phase analysis of training data in a signal from an MR wireless coil end comprises:
using pre-stored original training data to perform coherence phase analysis of training data in the digital signal sent from the second ADC.

In embodiments of the present disclosure, training data is inserted in MR data sent out by the MR wireless coil, pre-stored original training data is used at the MRI system to perform coherence phase analysis of the training data in the signal from the MR wireless coil, the phase offset between the second clock of the MRI system end and the first clock of the MR wireless coil end is calculated, the second clock is adjusted according to the phase offset so that the second clock and the first clock are synchronized, then the phase offset between the system clock and the second clock is obtained, and the MR data is synchronized to the system clock domain according to the phase offset obtained, thereby achieving synchronization of the system clock of the MRI system end and the data transmission clock of the MR wireless coil end, using the second clock as an intermediate clock, without needing to add any links, without needing to add a wireless receiving module, and without increasing the power consumption of the wireless coil.

### BRIEF DESCRIPTION OF THE DRAWINGS

Preferred embodiments of the present disclosure are described in detail below with reference to the drawings, to give those skilled in the art a clearer understanding of the abovementioned and other features and advantages of the present disclosure. In the drawings:

FIG. 1 is a schematic diagram showing the use of a wireless coil for MR signal transmission in an existing MRI system.

FIG. 2 is a flowchart of a method for clock synchronization in an MRI system as provided in embodiments of the present disclosure.

FIG. 3 shows an example of subjecting the MR data obtained by parsing in step 202 to phase offset correction according to the phase offset between the system clock and the second clock in step 205.

FIG. 4 is a structural schematic drawing of an apparatus for clock synchronization in an MRI system as provided in embodiments of the present disclosure.

FIG. 5 is a structural schematic drawing of an MRI system provided in embodiments of the present disclosure.

### KEY TO THE DRAWINGS

| Label | Meaning |
|---|---|
| 11 | Wireless coil end |
| 111 | Wireless coil |
| 112 | First ADC |
| 113 | First wireless module |
| 12 | System end |
| 121 | Second wireless module |
| 122 | Second ADC |
| 123 | Image reconstruction system |
| 201-205 | Steps |
| 31 | Signal sent by MR wireless coil end |
| 311 | MR data obtained by parsing in step 202 (i.e. MR data |
| | resulting from sampling of the MR signal by the MR |
| | wireless coil end), i.e. g_{d}(j) in formula (1) |
| 312 | phase offsets between the system clock and the second |
| | clock, i.e. a0ᵢ in formula (1) |
| 313 | MR data synchronized with the system clock and |
| | obtained by subjecting multiple g_{d}(j) to interpolation |
| | using a0ᵢ, i.e. gᵢ in formula(1) |
| 40 | Apparatus for clock synchronization in MRI system |
| 41 | First phase offset acquisition module |
| 42 | First synchronization module |
| 43 | Second phase offset acquisition module |
| 44 | Second synchronization module |
| 200 | Second clock |
| 300 | System clock |
| 51 | MR wireless coil end |
| 511 | First ADC |
| 512 | First wireless module |
| 52 | MR system end |
| 521 | Second wireless module |
| 522 | Second ADC |
| 100 | First clock |

### DETAILED DESCRIPTION OF THE DISCLOSURE

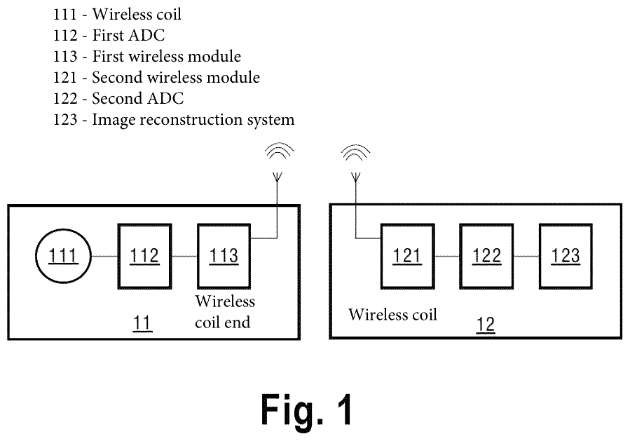

FIG. 1 is a schematic diagram showing the use of a wireless coil for MR signal transmission in an existing MRI system. A wireless coil 111 of a wireless coil end 11 receives an excited analog MR signal and transmits same to a first ADC (analog to digital converter) 112; the first ADC 112 samples the analog MR signal and converts same to a digital MR signal, and then transmits same to a first wireless module 113; the first wireless module 113 modulates the digital MR signal to a high-frequency signal and then transmits same via an antenna; the high-frequency signal is received by an antenna of a system end 12 and then enters a second wireless module 121 to undergo zero intermediate frequency processing, is then transmitted to a second ADC 122 to undergo analog to digital conversion, and is then transmitted through an optical fiber to an image reconstruction system 123.

Existing solutions for performing clock synchronization in a system using a wireless coil include the following:

1. A wireless infrared module is used to transmit a synchronization clock signal from the system end to the wireless coil end.

This solution has the following limitations: an infrared receiving module must be added to the wireless coil, and this increases the power consumption of the wireless coil; furthermore, due to the nature of infrared transmission, it requires face-to-face transmission to ensure better signal quality, so any unintended obstruction will affect the quality of the synchronization clock signal.

2. A common wireless communication module, such as a 2.4 GHz wireless module (e.g. Bluetooth, ZigBee, WIFI), a 5.8 GHz wireless module or a 60 GHz wireless module, is used to transmit a synchronization clock signal from the system end to the wireless coil end. However, an additional wireless receiving module must be added at the wireless coil end, and this increases the power consumption of the wireless coil; furthermore, if the communication channel suffers interference from another communication signal, the quality of the synchronization clock signal will also be affected.

3. The system end sends an RF (radio frequency) signal for MRI to the wireless coil end, and the wireless coil end returns an FID (free induction decay) signal and an RF signal to the system end by multiplexing, so as to calculate a phase offset between the system end and the wireless coil end. However, an additional link for receiving the RF signal must be added at the wireless coil end, and this increases the power consumption of the wireless coil.

4. The system end generates a dual pilot tone signal which avoids an MR frequency, and sends the dual pilot tone signal to the wireless coil end, to obtain a phase offset of the MR signal through a phase offset of the dual pilot tone signal. However, an additional link for receiving the dual pilot tone signal must be added at the wireless coil end, and this increases the power consumption of the wireless coil.

In addition, in solutions 3 and 4, data transmission is based on a standard wireless protocol, and an additional clock need not be provided for data transmission when a standard wireless protocol is used, but an MRI system is a self-defined wireless transmission scenario, in which two clocks (a system clock and a data transmission clock) need to be synchronized at the same time; for this reason, solutions 3 and 4 are not suitable for MRI systems

To clarify the objective, technical solutions and advantages of the present disclosure, the present disclosure is explained in further detail below through embodiments.

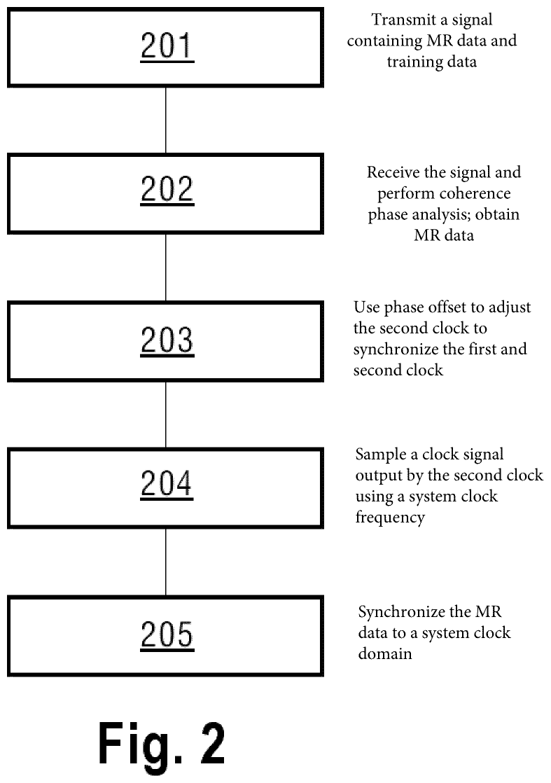

FIG. 2 is a flowchart of a method for clock synchronization in an MRI system as provided in embodiments of the present disclosure. The specific steps of the method being as follows:

Step 201: sending a signal containing MR data and training data from an MR wireless coil end, the MR data being data obtained by sampling according to a first clock by the MR wireless coil end, and the training data being inserted in the MR data.

In an optional embodiment, the first clock is a free-running clock, e.g. a clock generated by a crystal oscillator.

Step 202: the MRI system using a second clock as a reference clock, receiving the signal from the MR wireless coil end, using pre-stored original training data to perform coherence phase analysis of the training data in the signal to obtain a phase offset between the second clock and the first clock, and obtaining the MR data from the signal by parsing, wherein the original training data is data identical to the training data initially inserted in the MR data at the MR wireless coil end.

After the original training data has been inserted in the MR data at the MR wireless coil end and sent to the MRI system, when a phase offset exists between the second clock of the MRI system end and the first clock of the MR wireless coil end, in step 202, the original training data will differ from the training data in the signal from the MR wireless coil end which is received by the MRI system, and the phase offset between the second clock and the first clock can be obtained by using a coherence phase analysis algorithm to perform coherence phase analysis of the original training data and the training data in the signal received by the MRI system.

In an optional embodiment, the training data being inserted in the MR data in step 201 means that each training symbol set is inserted in the MR data according to a preset first interval, wherein each training symbol set consists of multiple training symbols inserted in the MR data according to a preset second interval, each training symbol set and the MR data in which it is inserted form a training sequence, and the original training data is data identical to an original training symbol set initially inserted in the MR data at the MR wireless coil end.

Moreover, in step 202, using pre-stored original training data to perform coherence phase analysis of the training data in the signal, to obtain a phase offset between the second clock and the first clock, comprises: using a sliding window of the same length as one training sequence, sliding the sliding window over the signal with a preset first length as a sliding step length, extracting each suspected training symbol from within the window according to the preset second interval on each occasion that sliding is performed, forming a suspected training symbol set from the suspected training symbols extracted from within the window, calculating a correlation of the suspected training symbol set and the original training symbol set, and respectively calculating a corresponding phase offset between the second clock and the first clock according to each periodically occurring correlation peak value, wherein the first length is 1 bit for example; the correlation peak values occur periodically because the training symbol sets are periodically inserted in the MR data.

Moreover, in step 202, obtaining the MR data from the signal by parsing comprises: confirming the suspected training symbol set in the window corresponding to each periodically occurring correlation peak value as a true training symbol set, and using data other than the true training symbol set within the window as MR data.

In an optional embodiment, the training symbol set is a plurality, e.g. a plurality of training symbol sets,
and in step 202, calculating a correlation of the suspected training symbol set and the original training symbol set comprises: performing a convolution operation on the suspected training symbol set and the original training symbol set, and calculating the modulus of a convolution result;
and in step 202, respectively calculating a corresponding phase offset between the second clock and the first clock, according to each periodically occurring correlation peak value, comprises: based on a peak value of the modulus of each periodically occurring convolution result, respectively calculating a phase angle of the convolution result corresponding to each peak value, each phase angle respectively being a phase offset between the second clock and the first clock.

Step 203: using the phase offset between the second clock and the first clock to adjust the second clock, so that the second clock and the first clock are synchronized.

The phase offset between the second clock and the first clock that is obtained by coherence phase analysis may be expressed as a multi-digit binary number. When the second clock is a clock generated by a voltage-controlled oscillator, in actual applications, the binary number can be converted to a signal level by a DAC, and the signal level can then be used to control the voltage-controlled oscillator, so that the second clock and the first clock are synchronized. In order to omit the DAC, in an optional embodiment, this step 203 specifically comprises: based on a preset linear relationship between phase offset and duty cycle, the phase offset between the second clock and the first clock is converted to a square wave signal with a corresponding duty cycle, which is then output to an integrator, and a level output by the integrator is used to adjust a frequency of a clock signal output by the voltage-controlled oscillator, so that the second clock and the first clock are synchronized. The duty cycle of the square wave signal and the phase offset have a linear relationship, which may for example be expressed as follows:
When the phase offset is a positive phase offset,

$$y = 50 \% + \frac{{x}^{+}}{{x}_{max}^{+}} \times 50 \% ,$$

wherein x⁺ is the positive phase offset, xₘₐₓ⁺ is the maximum positive phase offset, and y is the duty cycle;
When the phase offset is a negative phase offset,

$$y = 50 \% \frac{{x}^{-}}{{x}_{max}^{-}} \times 50 \% ,$$

wherein x⁻ is the negative phase offset, xₘₐₓ⁻ is the maximum negative phase offset, and y is the duty cycle;
As can be seen, a phase offset of 0 corresponds to a duty cycle of 50%, the maximum positive phase offset corresponds to a duty cycle of 100%, and the maximum negative phase offset corresponds to a duty cycle of 0%.

The voltage-controlled oscillator is for example a VCXO (voltage-controlled crystal oscillator).

Once the second clock and the first clock have been synchronized, the phase offset between the second clock and the first clock will fluctuate within a small range.

Step 204: using a system clock frequency as a sampling frequency to sample a clock signal output by the second clock, and calculating a phase offset between the system clock and the second clock on the basis of the sampled signal.

When the system clock frequency is used as a sampling frequency to perform a single sampling of the clock signal output by the second clock, a pair of I (In-phase) and Q (Quadrature) signals will be obtained, and a corresponding phase offset a between the system clock and the second clock can be calculated from the I and Q signal values, where a=arctg(Q/I).

Step 205: synchronizing the MR data obtained by parsing in step 202 to a system clock domain according to the phase offset between the system clock and the second clock.

In an optional embodiment, this step 205 specifically comprises: subjecting the MR data obtained by parsing in step 202 to phase offset correction according to the phase offset between the system clock and the second clock, and outputting the phase-offset-corrected MR data at an MR data sampling frequency of the MR wireless coil end according to the system clock.

In an optional embodiment, subjecting the MR data obtained by parsing in step 202 to phase offset correction according to the phase offset between the system clock and the second clock comprises the evaluation of:

$${g}_{1} = {\sum }_{j = i - m + 1}^{j = i + m} {g}_{d} ( j ) sinc ( \frac{a {0}_{i}}{2 π} - ( j - i ) ) \qquad ( 1 )$$

where gᵢ is the MR data resulting from the ith phase offset correction, i≥1, 2m is a preset number of interpolations, m being a preset positive integer, g_{d}(j) is the jth item of MR data obtained by parsing in step 202, j≥1, a0ᵢ is the phase offset between the system clock and the second clock that corresponds to the MR data resulting from the ith phase offset correction, a0ᵢ being expressed in radians, and sinc is a function name.

In actual applications, regarding the value of 2m, the greater the value of 2m, the higher the calculation precision of gᵢ and the longer the calculation time, so the calculation precision and calculation time of gᵢ can be taken into account together to set the value of 2m. When the value of 2m is small, e.g. 2m<a first threshold, a Hamming window or Hann window may be applied to

$$sinc ( \frac{a {0}_{i}}{2 π} - ( j - i ) )$$

to make gᵢ smoother; the specific value of the first threshold may be set according to experience, etc.

In an optional embodiment, a0ᵢ is the mean value of the (n*(i−1)+1)th to the (n*i)th phase offsets between the system clock and the second clock, calculated on the basis of the sampled signal when the system clock frequency is used as a sampling frequency to sample the clock signal output by the second clock, wherein n is the ratio of the system clock frequency to the MR data sampling frequency of the MR wireless coil end. For example: the system clock frequency is 10 MHZ, and the MR data sampling frequency of the MR wireless coil end is 1.25 Mhz, so n=10/1.25=8. Then: when the (8(i−1)+1)th to the (8i)th pairs of I and Q signals are obtained by using the system clock frequency as a sampling frequency to sample the clock signal output by the second clock, the (8(i−1)+1)th to the (8i)th phase offsets between the system clock and the second clock can be calculated; the mean value of the (8(i−1)+1)th to the (8i)th phase offsets is calculated, and this mean value is a0ᵢ.

Regarding step 205, once gᵢ has been obtained, gᵢ is output at the MR data sampling frequency of the MR wireless coil end. For example, the system clock frequency is 10 MHz, and the MR data sampling frequency of the MR wireless coil end is 1.25 MHz; then, using the system clock as a reference clock, each gᵢ is output at a frequency of 1.25 MHz, i.e. one gᵢ is output every 1/1.25=0.8 μs.

The range of values of a0ᵢ is [0, 2π]; if the mean value of the (n*(i−1)+1)th to the (n*i)th phase offsets mentioned above is used directly as a0ᵢ in actual applications, then a0ᵢ will jump periodically at intervals of π/4. Thus, after obtaining an initial value of a0ᵢ on the basis of the mean value of the (n*(i−1)+1)th to the (n*i)th phase offsets mentioned above, a preset function is used to convert the initial value of a0ᵢ, so that a0ᵢ varies uniformly within [0, 2π], wherein the preset function is for example an unwrap function.

Phase synchronization has now been achieved among three clocks with different sources: the first clock, the second clock, and the system clock.

In the embodiments above, training data is inserted in MR data sent out by the MR wireless coil, pre-stored original training data is used at the MRI system to perform coherence phase analysis of the training data in the signal from the MR wireless coil, the phase offset between the second clock of the MRI system end and the first clock of the MR wireless coil end is calculated, the second clock is adjusted according to the phase offset so that the second clock and the first clock are synchronized, then the phase offset between the system clock and the second clock is obtained, and the MR data is synchronized to the system clock domain according to the phase offset obtained, thereby achieving synchronization of the system clock of the MRI system end and the data transmission clock of the MR wireless coil end, using the second clock as an intermediate clock, without needing to add any links, without needing to add a wireless receiving module, and without increasing the power consumption of the wireless coil.

It should be explained that, regarding the coherence phase analysis algorithm, the imaginary part of the convolution result will be confused when the phase offset lies outside [−90°, 90°], so the range of phase offsets suitable for the coherence phase analysis algorithm is [−90°, 90°]. In actual applications, the following condition should be met when selecting the first clock and the second clock: a phase offset corresponding to a frequency difference between the first clock and the second clock should be within [−90°, 90°]. To meet this requirement, in an optional embodiment, before step 201, the method further comprises: obtaining a pre-defined maximum frequency difference between the second clock and the first clock; based on a transmission rate of a wireless system containing the MR wireless coil, a transmission rate of a wireless module of the MR wireless coil, and the length of the training sequence containing the training data used in a single coherence phase analysis, calculating a maximum phase offset corresponding to the pre-defined maximum frequency difference between the second clock and the first clock; and if the maximum phase offset is greater than 90°, re-selecting a first clock and/or second clock with a smaller pre-defined frequency error range, or reducing the length of the training sequence containing the training data used in a single coherence phase analysis. The maximum frequency difference between the second clock and the first clock can be obtained from technical handbooks for the first clock and the second clock, for example: if a frequency error range recorded in the technical handbook for the first clock is [−a,a] and a frequency error range recorded in the technical handbook for the second clock is [−b,b], then the frequency difference between the second clock and the first clock is [−b−a,b+a], i.e. the maximum frequency difference between the second clock and the first clock is a+b.

For example, let the transmission rate of the wireless system containing the MR wireless coil be f0=5.8 GHz, the transmission rate of the wireless module of the MR wireless coil be v=125 MHz, and the length of the training sequence containing the training data used in a single coherence phase analysis be l=3200 symbols; specifically, 1 training symbol is inserted in every 24 data symbols, and a total of 128 training symbols are used in each coherence phase analysis, so the length of each training sequence is l=128*25=3200 (symbols), wherein each symbol is generally 2 bits, in which case a transmission delay of each training sequence is dτ=3200/125 MHZ=25.6 us.

Then: if it is learned from the technical handbook of the second clock that the frequency error range of the second clock is ±0.5 ppm, and learned from the technical handbook of the first clock that the frequency error range of the first clock is ±0.5 ppm, then the maximum frequency difference between the second clock and the first clock is Δf=1 ppm, and the phase offset & corresponding to 1 ppm is calculated using the following calculation formula:

$$\begin{matrix}δ = 2 * π * f 0 * d τ * Δ f * 180 / π \\ = 2 * f 0 * d τ * Δ f * 180 \\ = 2 * ( 5.8 * {10}^{3} ) * 25.6 * ( 1 * {10}^{- 6} ) * 180 \\ = 53.4528 ° < 90 °\end{matrix} \qquad ( 2 )$$

As can be seen, the phase offset corresponding to the pre-defined maximum frequency difference Δf=1 ppm between the second clock and the first clock meets the requirement for coherence phase analysis.

It can also be seen from the calculation process above that: when the phase offset δ=90°, the corresponding frequency difference is 90/53.4528≈1.68 ppm; therefore, in this example, the requirement for coherence phase analysis can be met if the frequency difference between the second clock and the first clock is within [−1.68 ppm, 1.68 ppm].

It can also be seen from the calculation process above that: when the pre-defined maximum frequency difference between the second clock and the first clock does not meet the requirement for coherence phase analysis, a first clock and/or second clock with a smaller frequency error range can be re-selected, or the length of the training data used in a single coherence phase analysis can be reduced, because: the smaller the length of the training data used in a single coherence phase analysis, the smaller the transmission delay dr of each training sequence, the smaller the phase offset & corresponding to 1 ppm, and the greater the frequency difference between the second clock and the first clock that meets the coherence phase analysis requirement.

In actual applications, regarding step 204, an ADC synchronized with the system clock can be used to sample the clock signal output by the second clock, and the phase offset between the system clock and the second clock can be calculated on the basis of the sampled signal; once the second clock and the first clock have been synchronized, what is calculated on the basis of the sampled signal is in essence a phase offset between the system clock and the first clock. It should be explained that when the frequency of the second clock is greater than the frequency of the system clock, the second clock must first be subjected to frequency division, and a frequency-divided clock signal is then output, wherein the frequency of the frequency-divided clock signal is less than half the frequency of the system clock; the ADC synchronized with the system clock then samples the frequency-divided clock signal.

For example: the frequency of the system clock is 10 MHz, and the frequency of the second clock is frequency-divided from 40 MHz to 2.5 MHz, so when the system clock and the second clock are synchronized and have a fixed phase offset, the phase offset between the system clock and the second clock that is calculated on the basis of the sampled signal output by the ADC in step 204 will repeat 4 values: a0, a0+90°, a0+180° and a0−90°, where a0 is a constant; when the system clock and the second clock are not synchronized, a0 will drift slowly with time, e.g. with a frequency drift of 1 ppm, 40 MHz*1 ppm=40 Hz, so the frequency has a 40 Hz drift.

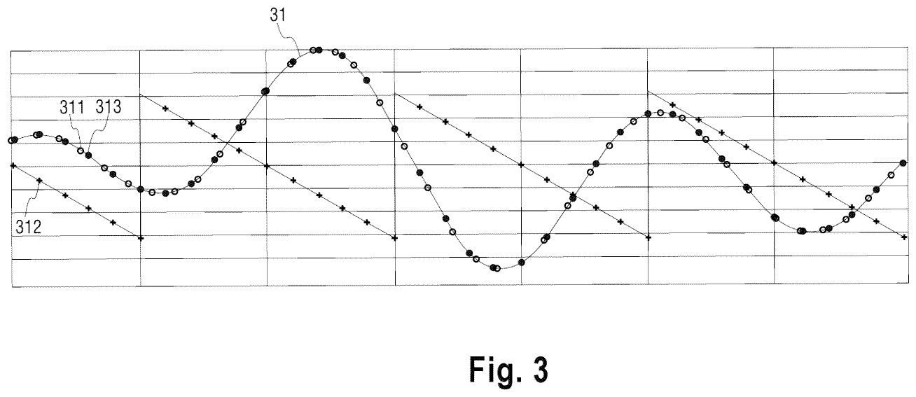

FIG. 3 shows an example of subjecting the MR data obtained by parsing in step 202 to phase offset correction according to the phase offset between the system clock and the second clock in step 205:

As shown in FIG. 3, curve 31 is a signal from the MR wireless coil end, the hollow dots 311 in FIG. 3 are MR data obtained by parsing in step 202 (i.e. MR data resulting from sampling of the MR signal by the MR wireless coil end), i.e. g_{d}(j) in formula (1), the crosses in FIG. 3 are phase offsets between the system clock and the second clock, i.e. a0ᵢ in formula (1), and the solid dots 313 in FIG. 3 are MR data synchronized with the system clock and obtained by subjecting multiple g_{d}(j) to interpolation using a0i, i.e. g; in formula (1). In FIG. 3, the horizontal coordinates are time t, and the vertical coordinates are the phase offset or relative intensity of the MR signal.

It must be explained that, in order to explain in a more visually direct way the process of subjecting multiple g_{d}(j) to interpolation by a0ᵢ to obtain gᵢ, only 10 g; are used in one period as an example. In actual applications, the quantity of MR data in one period is very large, and the phase drift of data is a slow process. For example: if the first clock and the system clock have a frequency difference of 1 ppm, and the frequency of the first clock is 40 MHZ, 40 MHz*1 ppm=40 Hz, so the frequency will have a 40 Hz drift, 1/40 Hz=25 ms; if the MR data sampling frequency of the MR wireless coil end is 1.25 MHz, 1.25 MHz*25 ms=31250, so there will be 31250 items of MR data within the duration of one period (360° or 2π) of drift of the phase offset between the system clock and the first clock.

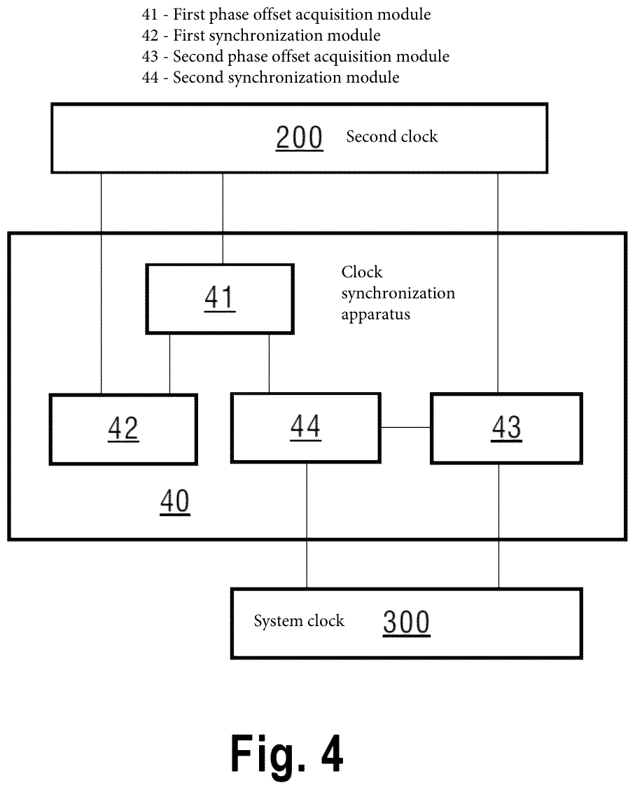

FIG. 4 is a structural schematic drawing of an apparatus for clock synchronization in an MRI system as provided in embodiments of the present disclosure, the apparatus mainly comprising: a first phase offset acquisition module 41, a first synchronization module 42, a second phase offset acquisition module 43 and a second synchronization module 44, wherein:
the first phase offset acquisition module 41 is configured to use pre-stored original training data to perform coherence phase analysis of training data in a signal from an MR wireless coil end, using a second clock 200 as a reference clock, to obtain a phase offset between the second clock 200 and the first clock, send the phase offset between the second clock 200 and the first clock to a first synchronization module 42, obtain MR data by parsing from the signal, and send the MR data obtained by parsing to the second synchronization module 44, wherein the signal contains MR data and training data, the MR data being data obtained by sampling according to the first clock by the MR wireless coil end, and the training data being inserted in the MR data; and the original training data is data identical to the training data initially inserted in the MR data at the MR wireless coil end.

The first synchronization module 42 is configured to receive the phase offset between the second clock 200 and the first clock which is sent by the first phase offset acquisition module 41, and use the phase offset between the second clock 200 and the first clock to adjust the second clock 200, so that the second clock 200 and the first clock are synchronized.

The second phase offset acquisition module 43 is configured to use a frequency of a system clock 300 as a sampling frequency to sample a clock signal output by the second clock 200, calculate a phase offset between the system clock 300 and the second clock 200 on the basis of the sampled signal, and send the phase offset between the system clock 300 and the second clock 200 to the second synchronization module 44.

The second synchronization module 44 is configured to receive the phase offset between the system clock 300 and the second clock 200 which is sent by the second phase offset acquisition module 43, and synchronize the MR data obtained by parsing by the first phase offset acquisition module 41 to a system clock domain according to the phase offset between the system clock 300 and the second clock 200.

In an optional embodiment, the training data being inserted in the MR data means that each training symbol set is inserted in the MR data according to a preset first interval, wherein training symbols in each training symbol set are inserted in the MR data according to a preset second interval, each training symbol set and the MR data in which it is inserted form a training sequence, and the original training data is data identical to an original training symbol set initially inserted in the MR data at the MR wireless coil end.

The first phase offset acquisition module 41 using pre-stored original training data to perform coherence phase analysis of the training data in the signal from the MR wireless coil end, to obtain a phase offset between the second clock 200 and the first clock, comprises: using a sliding window of the same length as one training sequence, sliding the sliding window over the signal with a preset first length as a sliding step length, extracting suspected training symbols from within the window according to the preset second interval on each occasion that sliding is performed, forming a suspected training symbol set from the suspected training symbols extracted from within the window, calculating a correlation of the suspected training symbol set and the original training symbol set, and respectively calculating a corresponding phase offset between the second clock 200 and the first clock according to each periodically occurring correlation peak value;
the first phase offset acquisition module 41 obtaining MR data by parsing from the signal comprises: confirming the suspected training symbol set in the window corresponding to each periodically occurring correlation peak value as a true training symbol set, and using data other than the true training symbol set within the window as MR data.

In an optional embodiment, the training symbol set is a plurality,
the first phase offset acquisition module 41 calculating a correlation of the suspected training symbol set and the original training symbol set comprises: performing a convolution operation on the suspected training symbol set and the original training symbol set, and calculating the modulus of a convolution result;
the first phase offset acquisition module 41 respectively calculating a corresponding phase offset between the second clock and the first clock, according to each periodically occurring correlation peak value, comprises: based on a peak value of the modulus of each periodically occurring convolution result, respectively calculating a phase angle of the convolution result corresponding to each peak value, each phase angle respectively being a phase offset between the second clock and the first clock.

In an optional embodiment, the second clock 200 is a clock generated by a voltage-controlled oscillator, and the first synchronization module 42 using the phase offset between the second clock 200 and the first clock to adjust the second clock 200 comprises: based on a preset linear relationship between phase offset and duty cycle, converting the phase offset between the second clock 200 and the first clock to a square wave signal with a corresponding duty cycle, outputting the square wave signal to an integrator, and using a level output by the integrator to adjust a frequency of a clock signal output by the voltage-controlled oscillator.

In an optional embodiment, the second synchronization module 44 synchronizing the MR data obtained by parsing by the first phase offset acquisition module 41 to a system clock domain, according to the phase offset between the system clock 300 and the second clock 200, comprises: subjecting the MR data obtained by parsing by the first phase offset acquisition module 41 to phase offset correction according to the phase offset between the system clock 300 and the second clock 200, and outputting the phase-offset-corrected MR data at an MR data sampling frequency of the MR wireless coil end according to the system clock 300.

In an optional embodiment, the second synchronization module 44 subjecting the MR data obtained by parsing to phase offset correction, according to the phase offset between the system clock 300 and the second clock 200, comprises:

$${g}_{i} = {\sum }_{j = i - m + 1}^{j = i + m} {g}_{d} ( j ) sinc ( \frac{a {0}_{i}}{2 π} - ( j - i ) )$$

where gᵢ is the MR data resulting from the ith phase offset correction, i≥1, 2m is a preset number of interpolations, m being a preset positive integer, g_{d}(j) is the jth item of MR data obtained by parsing, j≥1, a0ᵢ is the phase offset between the system clock 300 and the second clock 200 that corresponds to the MR data resulting from the ith phase offset correction, a0ᵢ being expressed in radians, and sinc is a function name.

In an optional embodiment, the second synchronization module 44 obtains a0ᵢ in the following way: using as a0ᵢ the mean value of the (n*(i−1)+)th to the (n*i)th phase offsets between the system clock 300 and the second clock 200 which are calculated by the second phase offset acquisition module 43, wherein n is the ratio of the system clock frequency to the MR data sampling frequency of the MR wireless coil end.

In an optional embodiment, the apparatus 40 for clock synchronization in an MRI system is located on an FPGA (field programmable gate array, programmable logic array).

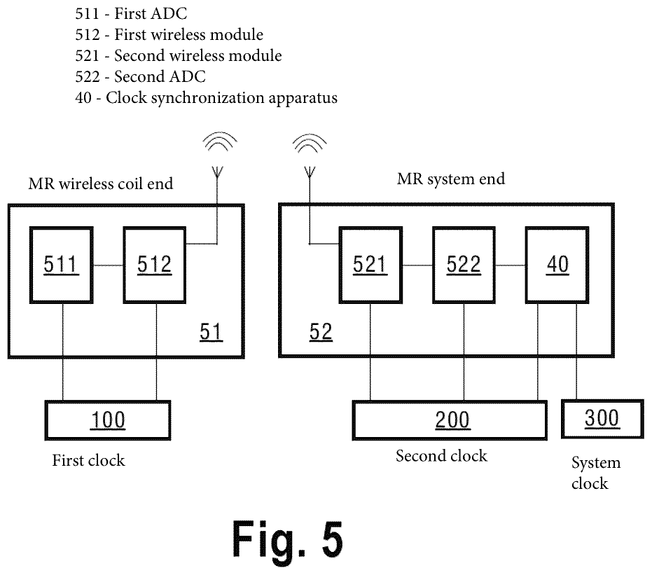

FIG. 5 is a structural schematic drawing of an MRI system provided in embodiments of the present disclosure, the MRI system mainly comprising: a first ADC 511 and a first wireless module 512, which are located at an MR wireless coil end 51; and a second wireless module 521, a second ADC 522 and the above-described apparatus 40 for clock synchronization in an MRI system, which are located at an MR system end 52, wherein:
the first ADC 511 is configured to use a first clock 100 as a reference clock, convert an MR signal acquired by a wireless coil from an analog MR signal to a digital MR signal, sample the digital MR signal at a preset sampling frequency to obtain sampled MR data, insert original training data in the MR data obtained by sampling according to a preset training data insertion rule to obtain a training sequence, and transmit the training sequence to the first wireless module 512.

The first wireless module 512 is configured to use the first clock 100 as a reference clock, receive the training sequence sent by the first ADC 511, modulate a frequency of the training sequence to a preset frequency and then send out same via a wireless antenna.

The preset frequency is for example 5.8 GHz.

The second wireless module 521 is configured to use a second clock 200 as a reference clock, receive the training sequence from a wireless antenna, subject the training sequence to zero intermediate frequency processing to convert same to a baseband signal, and then transmit same to the second ADC 522.

The second ADC 522 is configured to use the second clock 200 as a reference clock, receive the baseband signal sent by the second wireless module 521, convert the baseband signal to a digital signal and then send same to the apparatus 40 for clock synchronization in an MRI system.

Moreover, the first phase offset acquisition module 41 in the apparatus 40 for clock synchronization in an MRI system using pre-stored original training data to perform coherence phase analysis of training data in a signal from an MR wireless coil end comprises: using pre-stored original training data to perform coherence phase analysis of training data in the digital signal sent from the second ADC 522.

As can be seen, once the apparatus 40 for clock synchronization in an MRI system has adjusted the second clock 200 according to the phase offset between the second clock 200 and the first clock 100, the adjusted second clock 200 is further used as a reference clock by the second wireless module 521 and the second ADC 522; in this way, a feedback loop is formed, influencing the subsequent phase offset between the second clock 200 and the first clock 100, until the second clock 200 and the first clock 100 attain synchronization.

Those skilled in the art will understand that features stated in embodiments and/or claims of the present disclosure can be combined and/or integrated in various ways, even if such combinations or integrations are not clearly stated in the present application. In particular, without departing from the spirit and teaching of the present application, features stated in embodiments and/or claims of the present application can be combined and/or integrated in various ways, and all such combinations and/or integrations fall within the scope of disclosure of the present application.

Specific embodiments have been used herein to expound the principles and forms of implementation of the present application, but the description of the embodiments above is merely intended to help understand the method of the present application and the core idea thereof, not to restrict the present application. Those skilled in the art can make changes in terms of the specific form of implementation and the application scope, based on the idea, spirit and principles of the present application, and any modification, equivalent replacement or improvement, etc. that is made should be included in the scope of protection of the present application.

The various components described herein may be referred to as “modules.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units and/or devices, as applicable and relevant, may alternatively be referred to herein as “circuitry,” “controllers,” “processors,” or “processing circuitry,” or alternatively as noted herein.

What is claimed is:

1. A method for clock synchronization in a magnetic resonance imaging (MRI) system, comprising:
transmitting, from an MR wireless coil end, a signal containing MR data and training data,
wherein the MR data being data is obtained by sampling according to a first clock by the MR wireless coil end, and the training data is inserted in the MR data;
receiving, using a second clock as a reference clock, the signal from the MR wireless coil end;
performing, using pre-stored original training data, coherence phase analysis of the training data in the signal to obtain a phase offset between the second clock and the first clock;
obtaining the MR data from the signal via parsing,
wherein the original training data is identical to the training data inserted in the MR data at the MR wireless coil end,
adjusting, using the phase offset between the second clock and the first clock, the second clock to synchronize the first clock and the second clock;
sampling, using a system clock frequency as a sampling frequency, a clock signal output by the second clock;
calculating a phase offset between the system clock and the second clock based upon the sampled signal; and
synchronizing the MR data obtained by parsing to a system clock domain according to the phase offset between the system clock and the second clock.

2. The method as claimed in claim 1, wherein:
the training data inserted in the MR data comprises each training symbol set being inserted in the MR data according to a preset first interval,
training symbols in each training symbol set are inserted in the MR data according to a preset second interval,
each training symbol set and the respective MR data in which it is inserted form a training sequence,
the original training data is identical to an original training symbol set initially inserted in the MR data at the MR wireless coil end;
performing the coherence phase analysis of the training data in the signal comprises:
sliding, using a sliding window of the same length as a training sequence, the sliding window over the signal having a preset first length as a sliding step length;
extracting suspected training symbols within the sliding window according to the preset second interval on each occasion that sliding is performed;
forming a suspected training symbol set from the suspected training symbols extracted from within the sliding window;
calculating a correlation of the suspected training symbol set and the original training symbol set; and
respectively calculating a corresponding phase offset between the second clock and the first clock according to each periodically occurring correlation peak value, and
wherein the obtaining the MR data from the signal by parsing comprises:
confirming the suspected training symbol set in the sliding window corresponding to each periodically occurring correlation peak value as a true training symbol set; and
using data other than the true training symbol set within the sliding window as the MR data.

3. The method as claimed in claim 2, wherein:
the training symbol set comprises a plurality of training symbol sets,
calculating the correlation of the suspected training symbol set and the original training symbol set comprises:
performing a convolution operation on the suspected training symbol set and the original training symbol set, and calculating a modulus of a convolution result;
respectively calculating the corresponding phase offset between the second clock and the first clock according to each periodically occurring correlation peak value comprises:
respectively calculating, based on a peak value of the modulus of each periodically occurring convolution result, a phase angle of the convolution result corresponding to each peak value, each phase angle respectively being a phase offset between the second clock and the first clock.

4. The method as claimed in claim 1, wherein:
the second clock comprises a clock generated by a voltage-controlled oscillator,
adjusting the second clock comprises:
converting, based on a preset linear relationship between phase offset and duty cycle, the phase offset between the second clock and the first clock to a square wave signal with a corresponding duty cycle;
outputting the square wave signal to an integrator; and
adjusting, using a level output by the integrator, a frequency of a clock signal output by the voltage-controlled oscillator.

5. The method as claimed in claim 1, wherein the first clock comprises a free-running clock.

6. The method as claimed in claim 1, further comprising:
using a second clock as a reference clock prior to obtaining the MR data and training data by parsing;
obtaining a predefined maximum frequency difference between the second clock and the first clock;
calculating, based on a transmission rate of a wireless system containing the MR wireless coil, a transmission rate of a wireless module of the MR wireless coil, and a length of a training sequence containing the training data used in a single coherence phase analysis, a maximum phase offset corresponding to the predefined maximum frequency difference between the second clock and the first clock; and
in response to the maximum phase offset being greater than 90°, (i) re-selecting a first clock and/or second clock with a smaller predefined frequency error range, or (ii) reducing the length of the training sequence containing the training data used in a single coherence phase analysis.

7. The method as claimed in claim 1, wherein the synchronizing the MR data obtained by parsing to the system clock domain comprises:
subjecting the MR data obtained by parsing to phase offset correction according to the phase offset between the system clock and the second clock; and
outputting the phase-offset-corrected MR data at an MR data sampling frequency of the MR wireless coil end according to the system clock.

8. The method as claimed in claim 7, wherein the subjecting the MR data obtained by parsing to the phase offset correction comprises evaluating:
$${g}_{i} = {\sum }_{j = i - m + 1}^{j = i + m} {g}_{d} ( j ) sinc ( \frac{a {0}_{i}}{2 π} - ( j - i ) ) ,$$
wherein:
gᵢ represents the MR data resulting from the ith phase offset correction,
i≥1, 2m represents a preset number of interpolations, m being a preset positive integer,
g_{d}(j) represents a jth item of MR data obtained by parsing,
j≥1, a0ᵢ represents the phase offset between the system clock and the second clock that corresponds to the MR data resulting from an ith phase offset correction, and
a0ᵢ is expressed in radians.

9. The method as claimed in claim 8, wherein:
a0ᵢ represents a mean value of the (n*(i−1)+1)th to the (n*i)th phase offsets between the system clock and the second clock, which is calculated based upon the sampled signal when the system clock frequency is used as a sampling frequency to sample the clock signal output by the second clock, and
n represents the ratio of the system clock frequency to the MR data sampling frequency of the MR wireless coil end.

10. An apparatus for clock synchronization in a magnetic resonance imaging (MRI) system, comprising:
first phase offset acquisition circuitry configured to:
perform, using pre-stored original training data, coherence phase analysis of training data in a signal acquired via a magnetic resonance (MR) wireless coil end using a second clock as a reference clock;
obtain a phase offset between the second clock and a first clock;
obtain MR data from the signal via parsing,
wherein the signal contains MR data and training data,
wherein the MR data is data obtained by sampling according to the first clock by the MR wireless coil end,
wherein the training data is inserted in the MR data, and
wherein the original training data is identical to the training data inserted in the MR data at the MR wireless coil end;
first synchronization circuitry configured to adjust, using the phase offset between the second clock and the first clock, the second clock to synchronize the second clock and the first clock;
second phase offset acquisition circuitry configured to use a system clock frequency as a sampling frequency to sample a clock signal output by the second clock, and to calculate a phase offset between the system clock and the second clock based upon the sampled signal;
second synchronization circuitry configured to synchronize the MR data obtained by parsing to a system clock domain according to the phase offset between the system clock and the second clock.

11. The apparatus as claimed in claim 10, wherein:
the training data inserted in the MR data comprises each training symbol set being inserted in the MR data according to a preset first interval,
training symbols in each training symbol set are inserted in the MR data according to a preset second interval,
each training symbol set and the respective MR data in which it is inserted form a training sequence,
the original training data is identical to an original training symbol set initially inserted in the MR data at the MR wireless coil end;
the first phase offset acquisition circuitry is configured to perform, using pre-stored original training data, coherence phase analysis of training data in the signal to obtain a phase offset between the second clock and the first clock by:
sliding, using a sliding window of the same length as a training sequence, the sliding window over the signal having a preset first length as a sliding step length;
extracting suspected training symbols within the sliding window according to the preset second interval on each occasion that sliding is performed;
forming a suspected training symbol set from the suspected training symbols extracted from within the sliding window;
calculating a correlation of the suspected training symbol set and the original training symbol set; and
respectively calculating a corresponding phase offset between the second clock and the first clock according to each periodically occurring correlation peak value; and
the first phase offset acquisition circuitry is configured to obtain the MR data by parsing by confirming the suspected training symbol set in the sliding window corresponding to each periodically occurring correlation peak value as a true training symbol set, and using data other than the true training symbol set within the sliding window as the MR data.

12. The apparatus as claimed in claim 11, wherein:
the training symbol set comprises a plurality of training symbol sets,
the first phase offset acquisition circuitry is configured to calculate the correlation of the suspected training symbol set and the original training symbol set by performing a convolution operation on the suspected training symbol set and the original training symbol set, and calculating a modulus of a convolution result;
the first phase offset acquisition circuitry is configured to respectively calculate the corresponding phase offset between the second clock and the first clock according to each periodically occurring correlation peak value by respectively calculating, based on a peak value of a modulus of each periodically occurring convolution result, a phase angle of the convolution result corresponding to each peak value, each phase angle respectively being a phase offset between the second clock and the first clock.

13. The apparatus as claimed in claim 10, wherein:
the second clock comprises a clock generated by a voltage-controlled oscillator,
the first synchronization circuitry is configured to adjust the second clock using the phase offset between the second clock by:
converting, based on a preset linear relationship between phase offset and duty cycle, the phase offset between the second clock and the first clock to a square wave signal with a corresponding duty cycle;
outputting the square wave signal to an integrator; and
adjusting, using a level output by the integrator, a frequency of a clock signal output by the voltage-controlled oscillator.

14. The apparatus as claimed in claim 10, wherein the second synchronization circuitry is configured to synchronize the MR data obtained by parsing to the system clock domain by subjecting the MR data obtained by parsing to phase offset correction according to the phase offset between the system clock and the second clock, and outputting the phase-offset-corrected MR data at an MR data sampling frequency of the MR wireless coil end according to the system clock.

15. The apparatus as claimed in claim 14, wherein the second synchronization circuitry is configured to subject the MR data obtained by parsing to the phase offset correction by evaluating:
$${g}_{i} = {\sum }_{j = i - m + 1}^{j = i + m} {g}_{d} ( j ) sinc ( \frac{a {0}_{i}}{2 π} - ( j - i ) ) ,$$
wherein:
gᵢ represents the MR data resulting from the ith phase offset correction,
i≥1, 2m represents a preset number of interpolations, m being a preset positive integer,
g_{d}(j) represents a jth item of MR data obtained by parsing,
j≥1, a0ᵢ represents the phase offset between the system clock and the second clock that corresponds to the MR data resulting from an ith phase offset correction, and
a0ᵢ is expressed in radians.

16. The apparatus as claimed in claim 15, wherein the second synchronization circuitry is configured to obtain a0ᵢ by using as a0ᵢ a mean value of the (n*(i−1)+)th to the (n*i)th phase offsets between the system clock and the second clock, which are calculated by the second phase offset acquisition circuitry, and
wherein n represents the ratio of the system clock frequency to the MR data sampling frequency of the MR wireless coil end.

17. The apparatus as claimed in claim 10, wherein the apparatus for clock synchronization in the MRI system is implemented as a field programmable gate array (FPGA).

18. A magnetic resonance imaging (MRI) system, comprising:
an apparatus for clock synchronization located at a magnetic resonance (MR) system end;
a first analog-to-digital converter (ADC) and first wireless circuitry, which are located at a MR wireless coil end;
a second ADC and a second wireless circuitry, which are located at the MR system end, wherein:
the first ADC is configured to:
use a first clock as a reference clock;
convert an MR signal, acquired via a wireless coil, from an analog MR signal to a digital MR signal, sample the digital MR signal at a preset sampling frequency to obtain sampled MR data;
insert original training data in the MR data obtained by sampling according to a preset training data insertion rule to obtain a training sequence; and
transmit the training sequence to the first wireless circuitry;
the first wireless circuitry is configured to:
use the first clock as a reference clock;
receive the training sequence sent by the first ADC,
modulate a frequency of the training sequence to a preset frequency and transmit the modulated training sequence;
the second wireless circuitry is configured to:
use a second clock as a reference clock;
receive the training sequence from a wireless antenna;
subject the training sequence to zero intermediate frequency processing to convert the training sequence to a baseband signal and transmit the converted training sequence to the second ADC,
the second ADC is configured to:
use the second clock as a reference clock;
receive the baseband signal transmitted by the second wireless circuitry,
convert the baseband signal to a digital signal and transmit the converted baseband signal to the apparatus for clock synchronization in the MRI system; and
phase offset acquisition circuitry configured to synchronize the MRI system using pre-stored original training data to perform coherence phase analysis of training data in a signal from the MR wireless coil end using pre-stored original training data to perform coherence phase analysis of training data in the digital signal transmitted from the second ADC.
